(19) United States
(12) Patent Application Publication
(10) Pub. No.: US 2021/0234331 A1
(43) Pub. Date: Jul. 29, 2021

(54) OPTICAL MODULE, OPTICAL MODULE IMPLEMENTED SUBSTRATE, AND HOUSING

(71) Applicant: FURUKAWA ELECTRIC CO., LTD., Tokyo (JP)

(72) Inventors: Maiko ARIGA, Tokyo (JP); Yusuke INABA, Tokyo (JP); Kazuki YAMAOKA, Tokyo (JP)

(73) Assignee: FURUKAWA ELECTRIC CO., LTD., Tokyo (JP)

(21) Appl. No.: 17/228,913

(22) Filed: Apr. 13, 2021

Related U.S. Application Data
(63) Continuation of application No. PCT/JP2019/042037, filed on Oct. 25, 2019.

(30) Foreign Application Priority Data
Oct. 25, 2018 (JP) 2018-201062

(51) Int. Cl. H01S 5/022; H01S 5/22; H01S 5/02

(52) U.S. Cl. CPC H01S 5/022; H01S 5/0206; H01S 5/22

(57) ABSTRACT

An optical module includes: at least one optical element; a housing main body that houses therein the at least one optical element; and a plurality of lead pins that are provided to a side wall of the housing main body. Further, at least one of the lead pins is electrically connected to the at least one optical element, and the lead pins are lined up in a plurality of rows along a height direction of the side wall, and are arranged in such a manner that adjacent lead pins do not overlap each other in a top view.

### CROSS-REFERENCE TO RELATED APPLICATION(S)

This application is a continuation of International Application No. PCT/JP2019/042037, filed on Oct. 25, 2019 which claims the benefit of priority of the prior Japanese Patent Application No. 2018-201062, filed on Oct. 25, 2018, the entire contents of which are incorporated herein by reference.

### BACKGROUND

The present disclosure relates to an optical module, an optical module implemented substrate, and a housing.

Optical modules used for applications such as optical communication have a structure in which a plurality of optical elements such as a semiconductor laser device are housed inside a housing (see, for example, Japanese Laid-open Patent Publication No. 2002-299681, Japanese Patent No. 4494587, Japanese Laid-open Patent Publication No. 2001-284697, and Japanese Patent No. 4134564). Such a housing is provided with a large number of lead pins for electrically connecting the optical elements provided inside to an external controller, for example. Such an optical module is used in a manner implemented on an electric substrate. Usually, lead pins are lined up in a row, and extend from a surface perpendicular to an implementation surface of the housing so that a plane extending in parallel with the implementation surface is formed thereby. The implementation surface is a surface facing the electric substrate when the optical module is implemented on the electric substrate, and usually is the bottom surface of the housing of the optical module. Therefore, in the process of implementation, the tips of the lead pins are bent toward the implementation surface, and are fixed to the wiring pattern formed on the electric substrate by soldering, for example.

### SUMMARY

There is a need for providing an optical module, an optical module implemented substrate on which the optical module is implemented, and a housing that makes it possible to reduce the pitch size between the lead pins, and that can be easily implemented on the electric substrate.

According to an embodiment, an optical module includes: at least one optical element; a housing main body that houses therein the at least one optical element; and a plurality of lead pins that are provided to a side wall of the housing main body. Further, at least one of the lead pins is electrically connected to the at least one optical element, and the lead pins are lined up in a plurality of rows along a height direction of the side wall, and are arranged in such a manner that adjacent lead pins do not overlap each other in a top view.

According to an embodiment, a housing includes: a housing main body; and a plurality of lead pins that are provided to a side wall of the housing main body Further, the lead pins are lined up in a plurality of rows along a height direction of the side wall, and are arranged in such a manner that adjacent lead pins do not overlap each other in a top view.

### BRIEF DESCRIPTION OF THE DRAWINGS

FIG. 1A is a schematic illustrating a general structure of an optical module according to a first embodiment;

FIG. 1B is a schematic illustrating a general structure of the optical module according to the first embodiment;

FIG. 1C is a schematic illustrating a general structure of the optical module according to the first embodiment;

FIG. 1D is a schematic illustrating a general structure of the optical module according to the first embodiment;

FIG. 2A is a schematic illustrating the optical module having lead pins that are bent;

FIG. 2B is a schematic illustrating the optical module having lead pins that are bent;

FIG. 2C is a schematic illustrating the optical module having lead pins that are bent;

FIG. 2D is a schematic illustrating the optical module having lead pins that are bent;

FIG. 3 is a schematic illustrating a general structure of an optical module implemented substrate according to a second embodiment;

FIG. 4A is a schematic illustrating a general structure of an optical module according to a third embodiment; and

FIG. 4B is a schematic illustrating a general structure of an optical module according to a fourth embodiment.

### DETAILED DESCRIPTION OF THE PREFERRED EMBODIMENTS

In the related art, as the capacity of optical communication increases, there is a strong demand for reducing the size of the optical module. In order to reduce the size of the optical module, it is necessary to reduce the size of the housing. In order to provide a desired number of lead pins to a smaller housing, it is sometimes necessary to reduce the interval (pitch) between the lead pins to a size smaller than those used in the related art. However, if the size of the housing becomes even smaller, there is a chance that it becomes difficult to provide a predetermined number of lead pins to the housing.

A possible way for addressing this issue is to provide the lead pins in two levels in the direction perpendicular to the implementation surface (height direction). However, if the lead pins are provided in two levels in the height direction, there is a chance of the lead pins interfering one another, in the process of bending the lead pin toward the implementation surface, when the optical module is implemented on the electric substrate.

Some embodiments of the present disclosure will now be explained in detail with reference to the appended drawings. The embodiments explained below, however, are not intended to limit the scope of the present disclosure in any way. Furthermore, in the descriptions of the drawings, the same or corresponding elements are given the same reference numerals as appropriate, and redundant explanations thereof will be omitted as appropriate. Furthermore, it should be noted that the drawings are schematic representations, and the relative sizes of the elements, the ratio among the elements, and the like may differ from those in reality. Moreover, some of the relative sizes or the ratios among the elements may be represented differently among the drawings.

### First Embodiment

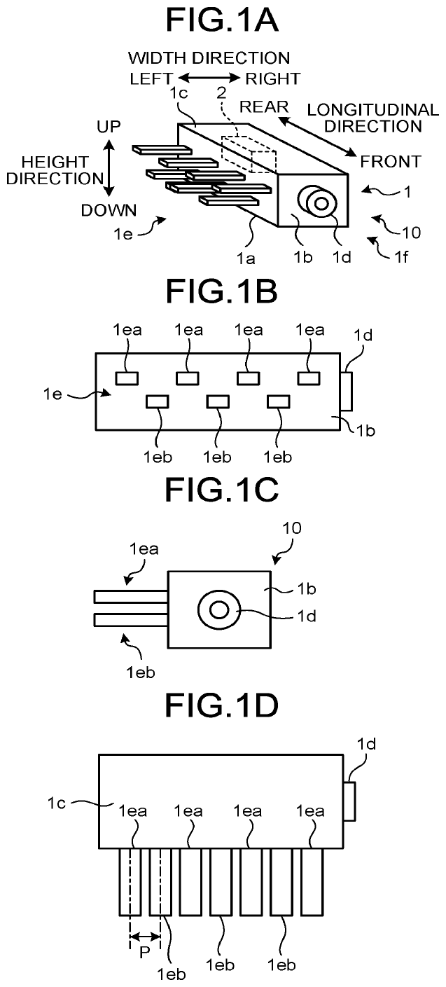

FIGS. 1A to 1D are schematics illustrating a general structure of an optical module according to a first embodiment. In FIG. 1A, a longitudinal direction, a width direction, and a height direction that are perpendicular to one another are defined to indicate directions. In FIGS. 1B to 1D, these directions also are defined in the same manner. FIG. 1A is a perspective view of this optical module 10; FIG. 1B is a schematic of the optical module 10 seen from the left side in the width direction; FIG. 1C is a schematic of the optical module 10 viewed from the front side in the longitudinal direction; and FIG. 1D is a top view of the optical module 10 viewed from above in the height direction.

The optical module 10 includes a housing 1 and an optical element 2. The housing 1 includes a bottom plate 1a, a side wall 1b, a top lid 1c, an optical port 1d, and a plurality of lead pins 1e. The bottom plate 1a is a plate-like member extending in the longitudinal and the width directions. The side wall 1b is a frame plate-like member having four sides each of which extends in the height direction and the longitudinal or the width direction, and that intersect with the bottom plate 1a substantially perpendicularly. The top lid 1c is a plate-like member facing the bottom plate 1a, and extending in the longitudinal and the width directions. The optical port 1d is provided on the front side of the side wall 1b in the longitudinal direction. The optical port 1d is a port via which light is output to the external, or via which light is input from the external, and an optical fiber for inputting or outputting the light is connected thereto.

The bottom plate 1a is made of a highly heat conductive material such as copper-tungsten (CuW), copper molybdenum (CuMo), aluminum oxide (Al₂O₃), aluminum nitride (AlN), and copper (Cu). The top lid 1c and the optical port 1d are made of materials with a low thermal expansion coefficient such as Fe—Ni—Co alloy, aluminum oxide (Al₂O₃), or aluminum nitride (AlN). The side wall 1b is also made of a material with a low thermal expansion coefficient, such as those described above, but a wiring area made of an insulating material is provided to a part of the side wall 1b, on the left side in the width direction. In the wiring area, a wiring pattern made of a conductive body is formed in a manner extending between inside and outside of the housing 1.

In the wiring area of the side wall 1b, a plurality of lead pins 1e made of a conductive body such as Fe—Ni—Co alloy or copper (Cu) are provided. On the surface of the lead pin 1e, nickel (Ni) or gold (Au) plating or a multilayer plating thereof may be provided to ensure solderability. The number of lead pins 1e in this embodiment is seven. The lead pins 1e will be explained later in detail.

The optical element 2 is housed inside a housing main body if defined by the bottom plate 1a, the side wall 1b, and the top lid 1c. The optical element 2 is an optical element that is caused to operate by receiving supplies such as power and electric signals. The optical element 2 is, for example, a semiconductor laser device, a semiconductor optical amplifier, an optical modulator, or a light-receiving element. Although the number of the housed optical elements 2 is one in this embodiment, the number of the optical elements 2 may be at least one, and it is also possible for a plurality of the optical elements 2 to be housed. The optical elements 2 may be optical elements of the same type, or those of different types. The optical element 2 is electrically connected to a controller provided to the external of the optical module 10 via a bonding wire, the wiring pattern on the wiring area, and at least one of the seven lead pins 1e. The controller is configured to control the operation of the optical module 10, mainly that of the optical element 2, and includes an integrated circuit (IC), for example.

The seven lead pins 1e are lined up in a plurality of rows (two rows, in this embodiment) in the height direction of the side wall 1b. In this embodiment, four lead pins 1ea out of the seven lead pins 1e are arranged in one row along the longitudinal direction, and three lead pins 1eb are arranged in one row along the longitudinal direction, below the four lead pins 1ea in the height direction.

Because the seven lead pins 1e are arranged in such a manner that two rows are formed thereby, it is possible to reduce the size of the pitch P between the adjacent lead pins 1ea, 1eb in the top view, as illustrated in FIG. 1D. Specifically, the pitch P can be made smaller than the pitch between the adjacent lead pins 1ea and between the lead pins 1eb in the same row, and may be set to 0.7 mm or less, for example. The pitch between the adjacent lead pins 1ea and between the lead pins 1eb in the same rows is restricted by factors such as the space required for the lead pins to be provided, assembly tolerance, and manufacturing tolerance, but in the embodiment, it is possible to achieve a pitch P smaller than that achieved with impositions of such restrictions.

In this embodiment, the seven lead pins 1e are arranged in such a manner that adjacent lead pins do not overlap each other in the top view, as illustrated in FIG. 1D. Such seven lead pins 1e are arranged in what is called a staggered arrangement. As a result, the lead pins 1e do not interfere with each other even when the tips of the lead pins 1e are bent toward the bottom surface of the housing 1.

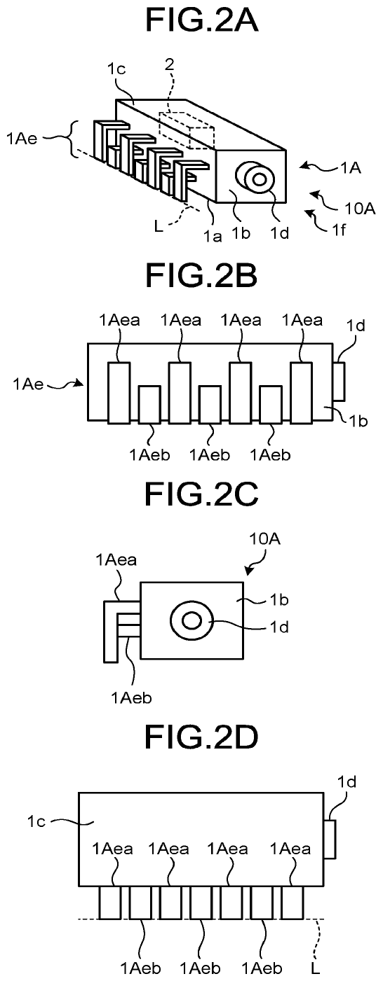

FIGS. 2A to 2D are schematics illustrating an optical module 10A in which the lead pins 1e of the optical module 10 are bent. FIG. 2A is a perspective view of the optical module 10A; FIG. 2B is a side view of the optical module 10A seen from the left side in the width direction; FIG. 2C is a schematic of the optical module 10A seen from the front side in the longitudinal direction; and FIG. 2D is a top view of the optical module 10A seen from above in the height direction. The optical module 10A is different from the optical module 10 in that a housing 1A includes seven bent lead pins 1Ae. In the optical module 10A, the tip sides of the lead pins 1Ae point to the bottom surface of the housing 1A in the height direction, and the tips are arranged substantially linearly along a line L that is substantially parallel with the side wall 1b where the lead pins 1Ae are provided. Specifically, the tips of the lead pins 1Aea and the tips of the lead pins 1Aeb are arranged alternatingly side by side along the line L.

With this configuration, compared with the configuration in which the tips of the lead pins are arranged in two rows, it is possible to implement the optical module 10A onto the electric substrate more easily, and with the module 10A implemented onto the electric substrate, it is possible to reduce the implementation area of the lead pins 1Ae in the electric substrate. In this manner, it is possible to increase the implementation density of the lead pins 1Ae on the electric substrate, and to reduce the implementation area as the entire optical module 10A.

### Second Embodiment

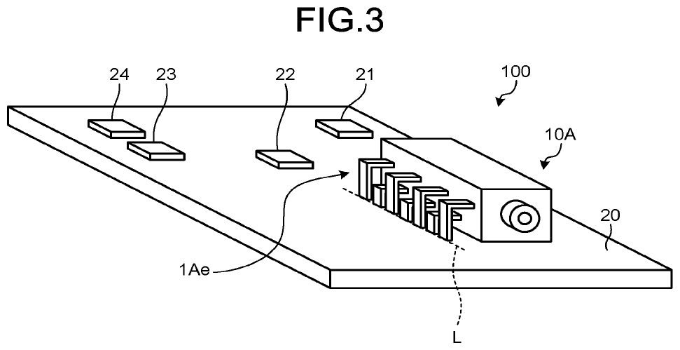

FIG. 3 is a schematic illustrating a general structure of an optical module implemented substrate according to a second embodiment. This optical module implemented substrate 100 includes the optical module 10A, and an electric substrate 20 on which the optical module 10A is implemented. In addition to the optical module 10A, a plurality of electronic devices including electronic devices 21, 22, 23, 24 are implemented on the electric substrate 20. The electric substrate 20 is also provided with a wiring pattern for electrically connecting these electronic devices and the optical module 10A. The electronic devices 21, 22, 23, 24 make up a controller for controlling the operation of the optical elements provided to the optical module 10A. This controller is electrically connected to a high level apparatus not illustrated via a connector pin, for example. This controller receives a command signal from the high level apparatus, for example, and controls the operations of the optical module 10A, mainly the operations of the optical elements 2.

With this optical module implemented substrate 100, it is possible to reduce the area where the lead pins 1Ae of the optical module 10A are implemented on the electric substrate 20, as described above. As a result, it is possible to increase the implementation density of the lead pins 1Ae, and to reduce the implementation area as the entire optical module 10A. Therefore, it is possible to achieve the electric substrate 20 with a smaller foot print.

In the embodiment described above, the optical module 10A is manufactured by bending the lead pins 1e of the optical module 10, but it is also possible to manufacture the optical module 10A by forming the shape of the lead pins 1Ae using a mold or the like, instead of bending.

### OTHER EMBODIMENTS

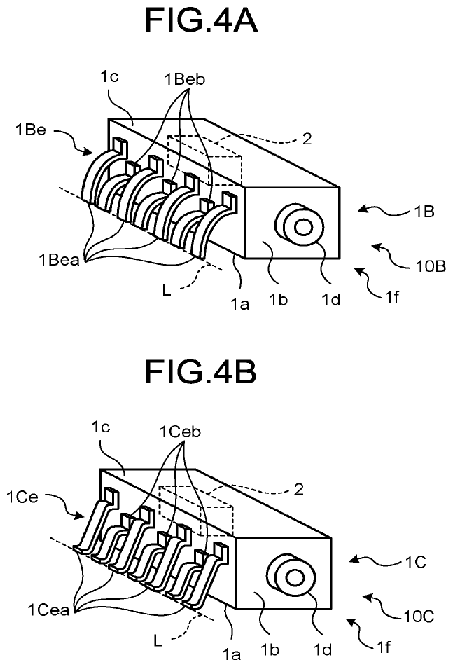

FIGS. 4A and 4B are schematics illustrating general structures of optical modules according to a third and a fourth embodiment, respectively.

An optical module 10B illustrated in FIG. 4A has a structure having a housing 1B, in replacement of the housing 1 included in the structure of the optical module 10 illustrated in FIGS. 1A to 1D. The housing 1B has a structure having lead pins 1Be, in replacement of the lead pins 1e included in the structure of the housing 1.

The seven lead pins 1Be are arranged in a staggered arrangement. Specifically, the seven lead pins 1Be are arranged in two rows in the height direction of the side wall 1b. Four lead pins 1Bea out of the seven lead pins 1Be are arranged in one low along the longitudinal direction, and three lead pins 1Beb are arranged in one row along the longitudinal direction, below the four lead pins 1Bea in the height direction. The seven lead pins 1Be are also arranged in such a manner that the adjacent lead pins do not overlap each other in the top view. Furthermore, the tip sides of lead pin 1Be point to the bottom surface in the height direction of the housing 1B (in the up-and-down direction in FIG. 4A), and the tips are arranged substantially linearly along the line L that is substantially parallel with the side wall 1b where the lead pins 1Be are provided.

With this configuration, it is possible to reduce the size of the pitch between the adjacent lead pins 1Bea, 1Beb to 0.7 mm or less in the top view, for example. Furthermore, it is possible to implement the optical module 10B onto the electric substrate more easily, and with the optical module 10B implemented onto the electric substrate, it is possible to reduce the implementation area of the lead pins 1Be on the electric substrate, to increase the implementation density of the lead pins, and to reduce the implementation area as the entire optical module 10B.

An optical module 10C illustrated in FIG. 4B has a structure having a housing 1C, in replacement of the housing 1 included in the structure of the optical module 10 illustrated in FIGS. 1A to 1D. The housing 1C has a structure having lead pins 1Ce, in replacement of the lead pins 1e included in the structure of the housing 1.

The seven lead pins 1Ce are arranged in a staggered arrangement. Specifically, the seven lead pins 1Ce are arranged in two rows in the height direction of the side wall 1b. The four lead pin 1Cea out of the seven lead pins 1Ce are arranged in one low along the longitudinal direction, and three lead pins 1Ceb are arranged in one row along the longitudinal direction, below the four lead pins 1Cea in the height direction. The seven lead pins 1Ce are also arranged in such a manner that the adjacent lead pins do not overlap each other in the top view. The tip sides of the lead pins 1Ce point to the bottom surface in the height direction of the housing 1C (in the up-and-down direction in FIG. 4B), and the tips are arranged substantially linearly along the line L that is substantially parallel with the side wall 1b where the lead pins 1Ce are provided.

With this configuration, it is possible to reduce the pitch between the adjacent lead pins 1Cea, 1Ceb to 0.7 mm or less in the top view, for example. Furthermore, it is possible to implement the optical module 10C onto the electric substrate more easily, and with the optical module 10C implemented onto the electric substrate, it is possible to reduce the implementation area of the lead pins 1Ce in the electric substrate, to increase the implementation density of the lead pins, and to reduce the implementation area as the entire optical module 10C.

In the optical modules according to the embodiments described above, e.g., in the optical module 10, the lead pins 1e are provided to only one surface that is the left surface of the side wall 1b in the width direction. Such a structure is suitable for implementing the optical module 10 together with another optical module paired with the optical module 10 onto an electric substrate. For example, when the optical module 10 is an optical transmitter module, the other module is an optical receiver module. Furthermore, by providing the other optical module with a mirror-symmetric structure with respect to that of the optical module 10 in the width direction, it is possible to implement the optical module 10 and the other optical module in such a manner that the housing main bodies thereof are positioned nearby each other.

In the embodiment described above, the lead pins are arranged in two rows in the height direction of the side wall, but may be arranged in three or more rows.

In the embodiment described above, the tip sides of the lead pins point to the bottom surface in the height direction of the housing. This is because, when the optical module according to the embodiment is implemented on a substrate or the like, the bottom surface of the optical module faces the substrate or the like. However, in a configuration in which the top surface of the optical module faces the substrate or the like when implemented on the substrate or the like, it is preferable for the tip sides of the lead pins to point the top surface of the housing in the height direction. In other words, it is preferable for the tip sides of the lead pins to point in a height direction of the housing, and to point to the bottom surface or the top surface depending on its implementation.

According to the present disclosure, the size of the pitch between the lead pins can be reduced, and the implementation onto the electric substrate is made easy, advantageously.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical module comprising:
at least one optical element;
a housing main body that houses therein the at least one optical element; and
a plurality of lead pins that are provided to a side wall of the housing main body, wherein
at least one of the lead pins is electrically connected to the at least one optical element, and
the lead pins are lined up in a plurality of rows along a height direction of the side wall, and are arranged in such a manner that adjacent lead pins do not overlap each other in a top view.

2. The optical module according to claim 1, wherein the at least one optical element is one or more optical elements of a same type or different types, out of a semiconductor laser device, a semiconductor optical amplifier, an optical modulator, and a light-receiving element.

3. The optical module according to claim 1, wherein the lead pins are arranged at a pitch equal to or smaller than 0.7 mm in a top view.

4. The optical module according to claim 1, wherein the lead pins are provided to only one surface of the side wall.

5. The optical module according to claim 1, wherein tip sides of the lead pins point in a height direction of the housing main body, and tips are arranged substantially linearly.

6. An optical module implemented substrate comprising:
the optical module according to claim 5; and
an electric substrate on which the optical module is implemented.

7. A housing comprising:
a housing main body; and
a plurality of lead pins that are provided to a side wall of the housing main body, wherein
the lead pins are lined up in a plurality of rows along a height direction of the side wall, and are arranged in such a manner that adjacent lead pins do not overlap each other in a top view.

8. The housing according to claim 7, wherein tip sides of the lead pins point in a height direction of the housing, and tips are arranged substantially linearly.
